(19) United States
(12) Patent Application Publication
(10) Pub. No.: US 2017/0018612 A1
(43) Pub. Date: Jan. 19, 2017

(54) SPLIT-GATE DEVICES

(71) Applicant: BROADCOM CORPORATION, Irvine, CA (US)

(72) Inventor: Akira ITO, Irvine, CA (US)

(21) Appl. No.: 14/820,444

(22) Filed: Aug. 6, 2015

Related U.S. Application Data
(60) Provisional application No. 62/192,524, filed on Jul. 14, 2015.

(51) Int. Cl. H01L 29/10; H01L 21/283; H01L 29/08; H01L 21/225; H01L 29/78; H01L 29/06

(52) U.S. Cl. CPC H01L 29/1095; H01L 29/7816; H01L 29/0696; H01L 29/0865; H01L 29/0882; H01L 21/2253; H01L 21/2254; H01L 21/283

(57) ABSTRACT

A semiconductor device includes a substrate having a source region and a drain region implanted with a second dopant by a second ion implantation. The substrate includes a first well region implanted with a first dopant by a first ion implantation and a second well region blocked from the first ion implantation forming a native section. The drain region is within the native section and the source region is within the first well region. The device includes a gate dielectric layer having a first region with a thickness different from that of a second region of the gate dielectric layer. The first region of the gate dielectric layer is located above the first well region and the second region of the gate dielectric layer is located above the second well region. The device includes a gate electrode disposed on the gate dielectric layer forming a gate structure on the substrate.

### CROSS-REFERENCE TO RELATED APPLICATION

The present application claims the benefit of U.S. Provisional Patent Application No. 62/192,524, entitled “SPLIT-GATE DEVICES,” filed Jul. 14, 2015, the contents of which are hereby incorporated by reference in its entirety for all purposes.

### TECHNICAL FIELD

The present application generally relates to semiconductor devices, and more particularly, but not exclusively, to split-gate laterally-diffused semiconductor devices and fabrication process thereof.

### BACKGROUND

A consequence of conventional field-effect transistor (FET) device scaling is a requirement to reduce operating voltages. The reduced operating voltages are required because conventional FET device scaling needs a relatively thin gate dielectric layer to produce the desired electrical characteristics in the scaled-down transistor. It has been recognized that many integrated circuit designs require both low operating voltage FETs for their ability to operate at high frequencies, and high operating voltage FETs for their ability to interface with high voltage signals of auxiliary devices. As such, FET devices include a lateral disposition of a core well (e.g., for low operating voltages) and an input/output (I/O) well (e.g., for high operating voltages). In this lateral disposition, there is an increase in doping concentration at the transition from the core well to the I/O well. As a result, the threshold voltage is relatively high for such FET device based on the combination of pocket implants and well implants.

### BRIEF DESCRIPTION OF THE DRAWINGS

Certain features of the subject disclosure are set forth in the appended claims. However, for purpose of explanation, several implementations of the subject disclosure are set forth in the following figures.

FIGS. 1A and 1B illustrate a planar view of a split-gate semiconductor device and a cross-sectional view of the split-gate semiconductor device along B-B′ according to one or more implementations.

FIGS. 2A and 2B illustrate a planar view of a split-gate semiconductor device with masked source regions and a cross-sectional view of the split-gate semiconductor device along B-B′ according to one or more implementations.

FIGS. 3A and 3B illustrate a planar view of a second split-gate semiconductor device with masked source regions and a cross-sectional view of the second split-gate semiconductor device along B-B′ according to one or more implementations.

FIGS. 4A and 4B illustrate a planar view of a split-gate semiconductor device with a masked drain region and a cross-sectional view of the split-gate semiconductor device along B-B′ according to one or more implementations.

FIGS. 5A and 5B illustrate a planar view of a second split-gate semiconductor device with a masked drain region and a cross-sectional view of the second split-gate semiconductor device along B-B′ according to one or more implementations.

FIG. 6 illustrates a sequential fabrication process for forming a split-gate semiconductor device according to one or more implementations.

### DETAILED DESCRIPTION

The detailed description set forth below is intended as a description of various configurations of the subject technology and is not intended to represent the only configurations in which the subject technology may be practiced. The appended drawings are incorporated herein and constitute a part of the detailed description. The detailed description includes specific details for the purpose of providing a thorough understanding of the subject technology. However, it will be clear and apparent to those skilled in the art that the subject technology is not limited to the specific details set forth herein and may be practiced using one or more implementations.

As used herein, the term “substrate” refers to the physical object that is the basic workpiece transformed by various process operations into the desired microelectronic configuration. A typical substrate used for the manufacture of integrated circuits is a wafer. Wafers may be made of semiconducting (e.g., bulk silicon), non-semiconducting (e.g., glass), or combinations of semiconducting and non-semiconducting materials (e.g., silicon-on-insulator (SOI)). In the semiconductor industry, a bulk silicon wafer is commonly used for the manufacture of integrated circuits.

As used herein, the term “gate structure” refers to an insulated gate terminal of a FET device. The physical structure of the gate terminal is referred to as a gate electrode. “Source/drain (S/D) terminals” refer to the terminals of a FET device between which conduction occurs under the influence of an electric field subsequent to inversion of the semiconductor surface under the influence of an electric field resulting from a voltage applied to the gate terminal of the FET device. Generally, the source and drain terminals of a FET are fabricated such that the source and drain terminals are geometrically symmetrical. With geometrically symmetrical source and drain terminals, these terminals can be simply referred to as source/drain terminals. Chip designers often designate a particular source/drain terminal to be a “source” or a “drain” on the basis of the voltage to be applied to that terminal when the FET device is operated in a circuit.

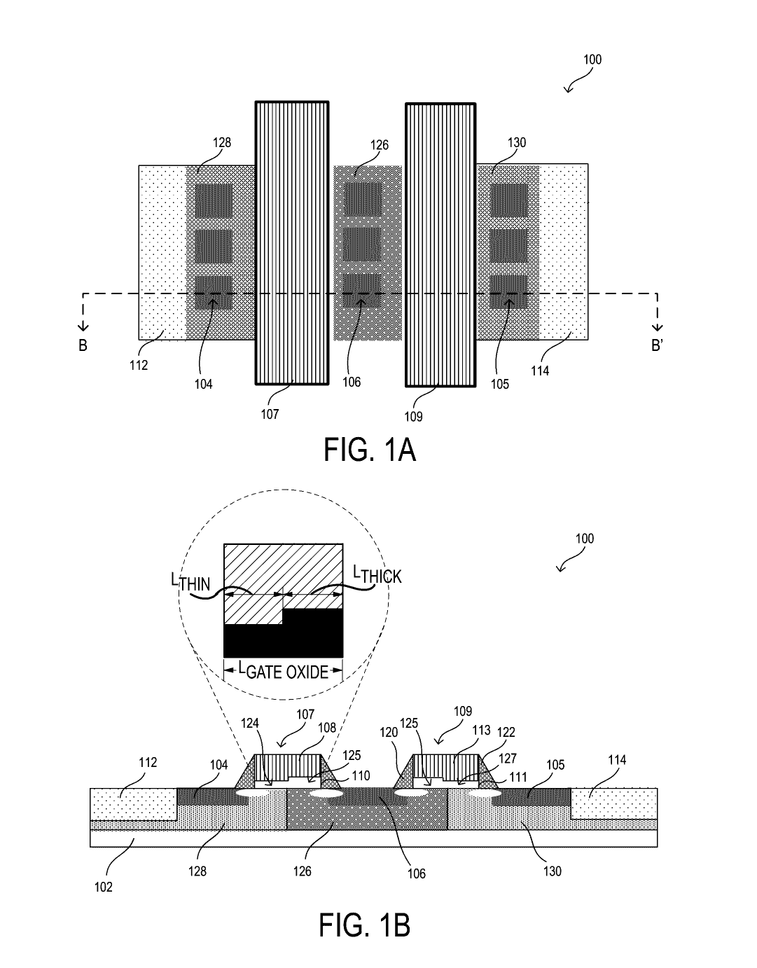

FIGS. 1A and 1B illustrate a planar view of a split-gate semiconductor device 100 and a cross-sectional view of the split-gate semiconductor device along B-B′ according to one or more implementations. Not all of the depicted components may be required, however, and one or more implementations may include additional components not shown in the figure. Variations in the arrangement and type of the components may be made without departing from the scope of the claims as set forth herein. Additional components, different components, or fewer components may be provided. In any implementation, what is shown as one layer of material (e.g., dielectric layer, metal layer, and so forth) may be realized with multiple layers of materials, where each layer may be of a thickness and/or material different from an adjacent layer.

The split-gate semiconductor device 100 is formed onto a substrate 102 of one conductivity type. For example, the split-gate semiconductor device 100 may be formed in the substrate 102 having a p-type material. The substrate 102 represents a physical material on which the split-gate semiconductor device 100 is formed. The p-type material includes impurity atoms of an acceptor type that are capable of accepting an electron, such as, but not limited to, boron or aluminum to provide some examples. Other materials such as gallium-arsenide, silicon-germanium, among other suitable substrate materials identifiable by a person skilled in the art may also be utilized in the process, in accordance with one or more implementations.

A first heavily doped region of substantially opposite conductivity as the substrate 102 represents a first source region 104 of the split-gate semiconductor device 100. In this embodiment, the first source region 104 represents an n-type source terminal for the split-gate semiconductor device 100. In one or more implementations, the first source region 104 contains a heavily doped region of substantially the same conductivity as the substrate 102, forming a p-type source terminal. Alternatively a raised source structure may be formed over a lightly doped source region (e.g., the first source region 104) by an epitaxial growth with in-situ doping or implant.

Generally, implanting a comparatively small number of atoms, approximately in a range of about 5×10¹⁸ atoms/cm³ to about 1×10¹⁹ atoms/cm³, refers to an implanting that is low or light. Similarly, implanting a comparatively large number of atoms, in a range of about 1×10¹⁹ atoms/cm³ to about 5×10²⁰ atoms/cm³, refers to an implanting that is high or heavy. The first source region 104 may include a first source region representing a first heavily doped region of substantially opposite conductivity as the substrate 102 and a second source region representing a lightly doped region of substantially opposite conductivity as the substrate 102, also referred to as an LDD region.

A second heavily doped region of substantially opposite conductivity as the substrate 102 represents a drain region 106 of the split-gate semiconductor device 100. In this embodiment, the drain region 106 represents an n-type drain terminal for the split-gate semiconductor device 100. In one or more implementations, the drain region 106 contains a heavily doped region of substantially the same conductivity as the substrate 102, forming a p-type drain terminal. Alternatively a raised drain structure may be formed over a lightly doped drain region (e.g., the first drain region 106) by an epitaxial growth with in-situ doping or implant.

The first source region 104 and the drain region 106 may be implanted with N+ material to form a first N+ region corresponding to the first source region 104 and a second N+ region corresponding to the drain region 106, respectively. The “+” indicates that the region is implanted with a higher carrier concentration than a region not designated by a “+.” For instance, an N+ region generally has a greater number of excess carrier electrons than an n-type region. A P+ region typically has a greater number of excess carrier holes than a p-type substrate. The n-type material includes impurity atoms of a donor type that are capable of donating an electron, such as, but not limited to, phosphorus, arsenic, or antimony to provide some examples.

A third heavily doped region of substantially opposite conductivity as the substrate 102 represents a second source region 105 of the split-gate semiconductor device 100. In this embodiment, the second source region 105 represents a second n-type source terminal for the split-gate semiconductor device 100. In one or more implementations, the second source region 105 contains a heavily doped region of substantially the same conductivity as the substrate 102, forming a second p-type source terminal.

Heavily doped regions of substantially opposite conductivity as the substrate 102 respectively represent a first gate structure 107 and a second gate structure 109 of the split-gate semiconductor device 100. Poly-crystalline silicon may be heavily implanted with a substantially opposite conductivity as the substrate 102 to respectively form the first gate structure 107 and the second gate structure 109. For example, the polycrystalline silicon may be implanted with N+ material to form a first N+ poly region, referred to as a gate electrode layer 108, corresponding to the first gate structure 107 and a second N+ poly region, referred to as a gate electrode layer 113, corresponding to the second gate structure 109. The first gate structure 107 is positioned between the first source region 104 and the drain region 106, and the second gate structure 109 is positioned between the drain region 106 and the second source region 105.

More specifically, as shown in FIG. 1B, at least a portion of the first gate structure 107 substantially overlaps the first source region 104 by a first substantially horizontal distance. It should be understood that relative spatial descriptions between one or more particular features, structures, or characteristics (e.g., “vertically aligned,” “contact,” etc.) used herein are for purposes of illustration only, and that practical implementations of the structures described herein may include fabrication or misalignment tolerances without departing from the scope of the present disclosure. A first side of the first source region 104 may extend beyond a first side of the first gate structure 107 by the first substantially horizontal distance such that at least a portion of the first source region 104 is below at least a portion of the first gate structure 107. Alternatively, the first side of the first gate structure 107 may be substantially vertically aligned with the first side of the first source region 104 such that no substantial overlap exists between the first source region 104 and the first gate structure 107. In some aspects, the first side of the first source region 104 may be positioned a second substantially horizontal distance from the first side of the first gate structure 107 such that none of the first source region 104 is below the first gate structure 107. In this regard, the second substantially horizontal distance separates the first side of the first gate structure 107 with the first side of the first source region 104.

Similarly, at least a portion of the second gate structure 109 substantially overlaps the second source region 105 by a first substantially horizontal distance. A first side of the second source region 105 may extend beyond a first side of the second gate structure 109 by the first substantially horizontal distance such that at least a portion of the second source region 105 is below at least a portion of the second gate structure 109. Alternatively, the first side of the second gate structure 109 may be substantially vertically aligned with the first side of the second source region 105 such that no substantial overlap exists between the second source region 105 and the second gate structure 109. In some aspects, the first side of the second source region 105 may be positioned a second substantially horizontal distance from the first side of the second gate structure 109 such that none of the second source region 105 is below the second gate structure 109. In this regard, the second substantially horizontal distance separates the first side of the second gate structure 109 with the first side of the second source region 105.

A gate dielectric layer 110 serves as an insulator between the first gate structure 107 and a channel region of the substrate 102 that is between the first source region 104 and the drain region 106. The gate dielectric layer 110 is positioned below and/or in contact with the first gate structure 107, between the first source region 104 and the drain region 106. Similarly, a gate dielectric layer 111 serves as an insulator between the second gate structure 109 and a second channel region of the substrate 102 that is between the second source region 105 and the drain region 106. The gate dielectric layer 111 is positioned below and/or in contact with the second gate structure 109, between the second source region 105 and the drain region 106. The gate dielectric layer 110 and the gate dielectric layer 111 may be formed using one or more layers of a dielectric material such as silicon dioxide (SiO₂), a high-K material, nitride-oxide, oxide, or any suitable material that can tolerate time-dependent dielectric breakdown (TDDB), hot carrier injection (HCI), or negative-bias temperature instability (NBTI) factors.

A first shallow-trench isolation (STI) region, referred to as a first isolation layer 112, and a second STI region, referred to as a second isolation layer 114, may provide isolation and/or protection for the split-gate semiconductor device 100 from neighboring active and passive elements integrated with and/or formed on the substrate 102. The first isolation layer 112 may be positioned adjacent to and/or in contact with a second side of the first source region 104. Likewise, the second isolation layer 114 may be positioned adjacent to and/or in contact with a first side of the second source region 105. The first isolation layer 112 and/or the second isolation layer 114 may be formed using a dielectric material such as SiO₂, though any suitable material may be used.

A first specially implanted p-type region is associated with high operating voltages; hence known as an I/O well region 126. The I/O well region 126 may be positioned below the drain region 106 and the first gate structure 107. The substrate 102 may be implanted with the p-type material to form the I/O well region 126. The I/O well region 126 may extend from a first side of the I/O well region 126 positioned below at least a portion of the first gate structure 107 to a second side of the I/O well region 126 positioned below at least a portion of the second gate structure 109 such that the I/O well region 126 extends below substantially all of the drain region 106.

A second specially implanted p-type region is associated with low operating voltages; hence known as a core well region 128. The core well region 128 may be positioned below the first source region 104 and the first gate structure 107. The substrate 102 may be implanted with the p-type material to form the core well region 128. In one or more implementations, the core well region 128 has a doping concentration that is substantially smaller than that of the I/O well region 126. As shown in FIG. 1A, the core well region 128 may include a first side being in contact with the first side of the I/O well region 126. The core well region 128 may extend from the first side positioned below at least a portion of the first gate structure 107 to a second side of the core well region 128 such that the core well region 128 extends below substantially all of the first source region 104 and the first isolation layer 112.

A third specially implanted p-type region is also associated with low operating voltages; hence known as a core well region 130. The core well region 130 may be positioned below the second source region 105 and the second gate structure 109. The substrate 102 may be implanted with the p-type material to form the core well region 130. In one or more implementations, the core well region 130 has a doping concentration that is substantially smaller than that of the I/O well region 126 and/or substantially the same as that of the core well region 128. As shown in FIG. 1A, the core well region 130 may include a first side being in contact with the second side of the I/O well region 126. The core well region 130 may extend from the first side positioned below at least a portion of the second gate structure 109 to a second side of the core well region 130 such that the core well region 130 extends below substantially all of the second source region 105 and the second isolation layer 114.

The split-gate semiconductor device 100 may include a spacer 120 above the first source region 104 and/or adjacent to the first gate structure 107 to isolate and/or protect the first source region 104 and the first gate structure 107 and a spacer 122 between the drain region 106 and the second side of the first gate structure 107 to isolate and/or protect the drain region 106 and the first gate structure 107. The spacer 120 and/or the spacer 122 may be formed using a dielectric material, such as SiO₂, though any suitable material may be used. The second gate structure 109 includes the spacers 120 and 122 in similar positions.

A p-n junction is a potential barrier created by combining the n-type and the p-type material. A first interface between the substrate 102 and the first source region 104 may represent a first p-n junction. Likewise, a second interface between the substrate 102 and the drain region 106 may represent a second p-n junction. The first p-n junction and/or the second p-n junction may prevent current conduction from the first source region 104 to the drain region 106 upon the application of a voltage from the first source region 104 to the drain region 106. On the other hand, applying a first potential, such as a positive direct current (DC) voltage to provide an example, to the first gate structure 107 and a second potential, such as a ground potential to provide an example, to the first source region 104 may cause a voltage to appear between the first gate structure 107 and the first source region 104. The first potential on the first gate structure 107 repels the positively charged carrier holes below the first gate structure 107 forming a channel region between the first source region 104 and the drain region 106 in the split-gate semiconductor device 100.

The channel region represents a carrier-depletion region populated by a negative charge formed below the gate dielectric layer 110 by an electric field. The electric field attracts carrier electrons from the first source region 104 and the drain region 106 into the channel region. An n-type region connecting the first source region 104 to the drain region 106 forms after a sufficient number of the carrier electrons accumulate in the channel region allowing current to flow from the first source region 104 to the drain region 106. However, there is a point, known as the breakdown voltage, where the current passing through the channel region increases uncontrollably resulting in breakdown. Examples of breakdown may include avalanche breakdown, punch-through, and/or gate oxide breakdown to provide some examples.

Gate oxide breakdown, also known as oxide rupture or oxide punch-through, refers to destruction of the gate dielectric layer 110. The gate oxide breakdown results from a build-up of defects inside the gate dielectric layer 110, which eventually leads to a creation of a conductive path in the gate dielectric layer 110 from the first gate structure 107 to the channel region. For example, a hot carrier effect may cause the defects inside the gate dielectric layer 110. The hot carrier effect refers to an effect of high energy carrier electrons and/or carrier holes generated as a result of impact ionization at the channel region. These high energy current carriers may leave the substrate 102 and may upon reaching a sufficiently high level of energy, tunnel into the gate dielectric layer 110 to cause the defects.

The gate oxide breakdown commences by the formation of the defects in the gate dielectric layer 110. At first, the defects are relatively small in number and do not form the conductive path in the gate dielectric layer 110. As the number of defects in the gate dielectric layer 110 increase, they eventually reach a point at which the conductive path forms in the gate dielectric layer 110 causing a soft breakdown. Movement of electrons from the channel region to the first gate structure 107 via the conductive path in the gate dielectric layer 110 further heats up the gate dielectric layer 110, which further increases the current flow through the conductive path. This increase in heat leads to more defects in the gate dielectric layer 110, thereby enlarging the conductive path and/or causing new conductive paths to form in the gate dielectric layer 110. As a result of the enlarged the conductive path and/or the new conductive paths, more defects form in the gate dielectric layer 110 eventually leading to a hard breakdown of the gate dielectric layer 110. The hard breakdown of the gate dielectric layer 110 causes the gate dielectric layer 110 to melt resulting in one or more permanent conductive paths in the gate dielectric layer 110 from the channel region to the first gate structure 107.

The split-gate semiconductor device 100 may be formed using a complementary metal oxide silicon (CMOS) logic foundry technology. The CMOS logic foundry technology may include one or more minimum design rules corresponding to one or more operating voltages. The minimum design rules represent minimum sizes of components of split-gate semiconductor device 100 and/or distances between the components of the split-gate semiconductor device 100 in accordance with the CMOS logic foundry. The CMOS logic foundry technology may include a specialized set of minimum design rules, such as a first set of minimum design rules for a low operating voltage process and/or a second set of minimum design rules for a high operating voltage process to provide some examples, for a corresponding operating voltage. For example, the CMOS logic foundry technology may include a first set of minimum design rules for a low operating voltage process of 1.0V, also referred to as a 1.0V process, and a high operating voltage process of 1.8V, also referred to as a 1.8V process. As another example, the CMOS logic foundry technology may include a first set of minimum design rules for a low operating voltage process of 1.2V, and a high operating voltage process of 2.5V, also referred to as a 2.5V process. Typically, the low operating voltage process is used for lower power devices with thinner gate oxides when compared with the high operating voltage process.

Core transistors (e.g., transistors operating in the core region) can switch at high speed (or high frequencies) but operate at low voltage, whereas I/O transistors (e.g., transistors operating in the I/O region) can operate at high voltage but switch at lower speeds. Disclosed herein are structures of FETs having a unique combination of properties, which are operable to interface with relatively high voltage signals and to simultaneously operate with relatively high cut-off frequency bands (f_{T}). It is noted that f_{T} refers to the frequency at which the small signal gain of the transistor drops to unity.

A conventional LDMOS device may be formed with the CMOS logic foundry technology using a combination of the low operating voltage process and the high operating voltage process or solely the high operating voltage process. In both of these situations, however, a gate dielectric layer, in its entirety, of the conventional LDMOS is formed using a thick gate oxide corresponding to the high operating voltage process. For example, the gate dielectric layer of the conventional LDMOS device may be formed using the thick gate oxide having a thickness of 4 nanometers (nm). The thick gate oxide increases the breakdown voltage of the conventional LDMOS device when compared to a thin gate oxide of the low operating voltage process. For example, the thin gate oxide of the low operating voltage process may have a thickness of 2 nm, to provide an example. However, an area of the thick gate oxide corresponding to the second set of minimum design rules for the high operating voltage process is greater than an area of the thin gate oxide corresponding to the first set of minimum design rules for the low operating voltage process. As a result of an increased area of the thick gate oxide, the conventional LDMOS device having the thick gate oxide is approximately 20% larger than an equivalent device having the thin gate oxide.

To mimic the increased breakdown voltage of the thick gate oxide, without the increase in size of the conventional LDMOS device, the gate dielectric layer 110 and the gate dielectric layer 111 of the split-gate semiconductor device 100 respectively use a split-gate oxide architecture. As shown in FIG. 1B, the gate dielectric layer 110 includes a first portion, referred to as a first gate oxide 124, having a first thickness and a second portion, referred to as a second gate oxide 125, having a second thickness. Similarly, the gate dielectric layer 111 includes a first portion, referred to as a first gate oxide 127, having a first thickness and a second portion, referred to as a second gate oxide 129, having a second thickness. In an exemplary embodiment, the first thickness may be approximately equal to the thin gate oxide of the low operating voltage process and the second thickness may be approximately equal to the thick gate oxide of the high operating voltage process. For example, the first thickness may be approximately 2 nm and the second thickness may be approximately 4 nm.

From the discussion above, the gate dielectric layer 110 is positioned below the first gate structure 107, between the first source region 104 and the drain region 106. The gate dielectric layer 110 may extend from a first side positioned adjacent to and/or in contact with the spacer 120 to a second side positioned adjacent to and/or in contact with the spacer 122 for a length of L_{GATE OXIDE}. The length of the gate dielectric layer 110 may be represented as:

L_{GATE OXIDE}=L_{THIN}+L_{THICK}, (1)

where L_{GATE OXIDE} represents the length of the gate dielectric layer 110, L_{THIN} represents a length of the first gate oxide 124, namely a first horizontal distance from the first side of the first gate oxide 124 to a second side of the first gate oxide 124, and L_{THICK} represents a length of the second gate oxide 125, namely a second horizontal distance from a first side of the second gate oxide 125 to a second side of the second gate oxide 125.

The first gate oxide 1124 may be positioned adjacent to and/or in contact with the spacer 120. The first gate oxide 124 may be positioned entirely above at least a portion of the core well region 128 for the length of L_{THIN}. The second side of the first gate oxide 124 may be positioned adjacent to and/or in contact with the first side of the second gate oxide 125 to form an oxide junction. The oxide junction may be vertically aligned with a boundary between the core well region 128 and the I/O well region 126. The second gate oxide 125 may be positioned entirely above at least a portion of the I/O well region 126 for the length of L_{THICK}. The length of L_{THIN} may be substantially equal to or smaller than the length of L_{THICK}.

As briefly described above, there is an increase in doping concentration at the transition from the core well region 128 to the I/O well region 126, for example. As a result, the threshold voltage is relatively high for such FET device. This is because the threshold voltage for such FET device may be defined by the combination of pocket implants (e.g., first source region 104, dram region 106) and well implants (e.g., core well region 128, I/O well region 126).

The subject disclosure relates to a split-gate semiconductor device which can support both low operating voltages (e.g., core) and high operating voltages (e.g., I/O) with the flexibility of reducing the threshold voltage by blocking well implants for certain well regions of the device. In one or more implementations, the core well is blocked when the I/O well receives well implants from a first ion implantation. In other implementations, the I/O well is blocked when the core well receives well implants from a second first ion implantation. In this regard, the number of well implants containing well dopants will be smaller compared to conventional devices containing well implants in all designated well regions. As a result, the sum of pocket implants and well implants will be smaller thereby forming a smaller threshold voltage for such FET device. In addition, the resistance across the source and drain of the device will be smaller due to the lesser number of regions between source and drain regions containing well implants. At a junction between a well region with well implants and an adjacent well region blocked from well implants, the junction capacitance will be smaller compared to conventional devices having adjacent well regions implanted with dopants. Another advantage of the aforementioned FET devices is that no additional fabrication process operations are needed to construct the transistor structures in accordance with one or more implementations of the subject technology.

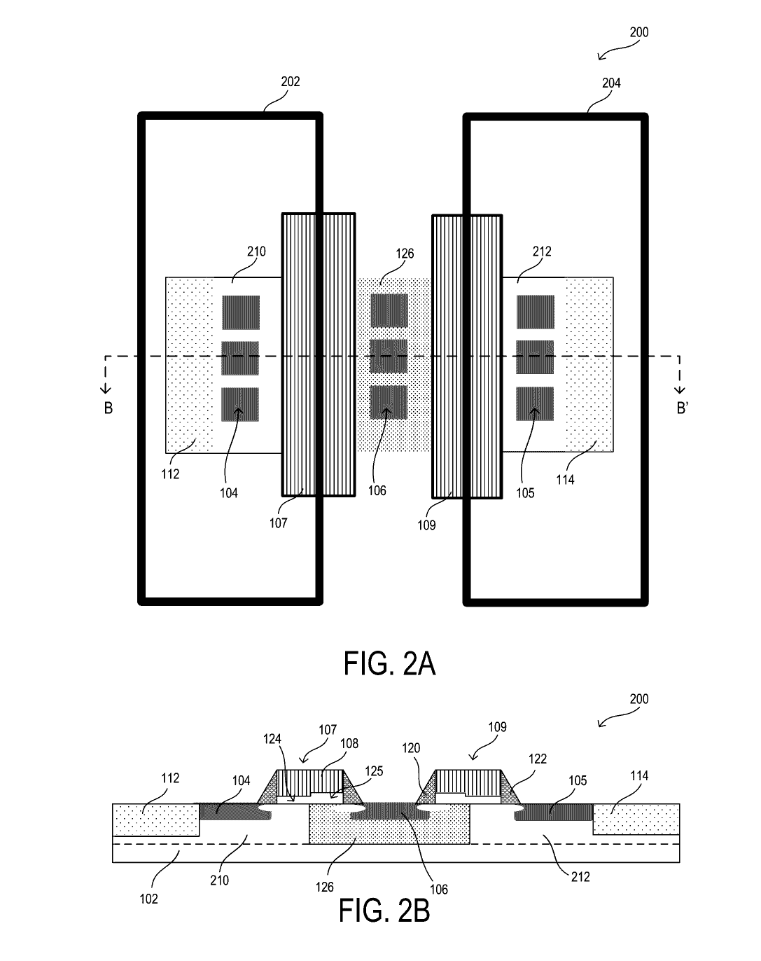

FIGS. 2A and 2B illustrate a planar view of a split-gate semiconductor device 200 with masked source regions and a cross-sectional view of the split-gate semiconductor device along B-B′ according to one or more implementations. Not all of the depicted components may be required, however, and one or more implementations may include additional components not shown in the figure. Variations in the arrangement and type of the components may be made without departing from the scope of the claims as set forth herein. Additional components, different components, or fewer components may be provided.

Because the features described in FIGS. 1A and 1B are similar to the features of FIGS. 2A and 2B, only differences between the figures will be described in reference to FIGS. 2A and 2B. For purposes of simplification, the implementations described in FIGS. 2A and 2B will be discussed primarily in reference to the first gate structure 107, the first source region 104 and the drain region 106; however, the implementations may be similarly applied to the second gate structure 109 and the second source region 105.

The split-gate semiconductor device 200 includes a substrate 102, such as a silicon (Si) substrate. The split-gate semiconductor device 200 also includes the first source region 104, the second source region 105, the drain region 106, the first gate structure 107, the second gate structure 109, the first isolation layer 112 and the second isolation layer 114. The laterally formed split-gate semiconductor devices are separated by a common drain terminal (e.g., the drain region 106) with respective sources terminals (e.g., the first source region 104, the second source region 105) located at near opposing ends of the FET devices. In this embodiment, the substrate 102 includes a doped I/O well beneath the drain region 106 and core well regions 210 and 212 (e.g., non-doped wells) respectively in contact with the first source region 104 and the second source region 105. The implementations with respect to FIGS. 2A and 2B may be implemented in n-type FET devices and p-type FET devices. For example, the substrate and the wells (e.g., core and I/O) may be p-type with n-type transistors (e.g., source and drain) for n-type FET devices. Alternatively, the substrate may be p-type and the wells may be n-type with p-type well transistors for p-type FET devices. In some implementations, the core well regions 210 and 212 are doped as part of a dopant applied to the substrate 102 prior to any well implantation.

In order to lower the threshold voltage of the laterally formed split-gate semiconductor devices, the core well regions 128 and 130 (FIG. 1B) are defined as a native layer (or section) of the substrate 102 without any well doping to increase current flow through the channel region thereby lowering the threshold voltage characteristics. In other words, during a first ion implantation such as a well implantation to implant a p-type material into the substrate 102, the core well region 210 is blocked from receiving the p-type well implants while a region designated as the I/O well (e.g., the I/O well region 126) is not blocked thereby exposed to the first ion implantation. In this respect, the threshold voltage for the split-gate semiconductor device 200 becomes a function of the well implants (e.g., the I/O well region 126) and pocket implants (e.g., the first source region 104, the drain region 106). In contrast, the threshold voltage for the split-gate semiconductor device 100 would be higher since the threshold voltage for such device is a function of the core well implants and the I/O well implant as well as the source/drain pocket implants.

In some aspects, the native layer represents one or more layers of the substrate 102 with bias properties (e.g., doped substrate) such that the native layer has a same doping concentration as that of the substrate 102. In some aspects, the doping concentration of the substrate 102 is substantially smaller than that of the I/O well region 126. For example, the doped substrate has a doping concentration of about 1×10¹⁵ atoms/cm³ whereas the I/O well region 126 has a doping concentration of about 3×10¹⁷ atoms/cm³. In this regard, the native layer having the core well regions 210 and 212 may have a doping concentration of about 1×10¹⁵ atoms/cm².

In one or more implementations, doping by the ion implantation is performed to implant dopants into the substrate 102 in regions not covered by a mask layer. Specifically, portions of the substrate 102 beneath the top surface are doped to form a doped portion of the substrate 102. The doping may be performed using one or more doping operations such as an ion implantation with a defined ion dosage to yield a certain doping concentration in the implanted region of the substrate 102. The ion implantation may be applied with a certain tilt angle and adjustable over a certain range of rotation. The doping can be n-type doping or p-type doping depending on implementation. In fabricating the split-gate semiconductor device 200, the substrate 102 receives n-type dopants or p-type dopants by an ion implantation depending on the type of semiconductor device targeted.

Prior to the first ion implantation, the mask layer is formed on the substrate 102. A layer of masking material such as photoresist may be deposited and patterned using semiconductor fabrication techniques to define regions protected by the masking material and regions not protected by the masking material. The mask layer may be patterned such that a section of the substrate 102 is blocked from the first ion implantation; hence a native section of the substrate 102. In this regard, the blocked section contains no doping concentration (if not negligible doping concentration) compared to the remainder of the substrate 102; hence a doped section of the substrate 102. As shown in FIG. 2A, mask layers 202 and 204 are provided on respective regions of the substrate 102 in order to protect the core well regions 210 and 212 from receiving the well implant dopants through the first ion implantation.

As shown in FIG. 2B, the substrate 102 has at least one well region implanted with a first dopant by the first ion implantation and the native section blocked from the first ion implantation. In one or more implementations, etching is performed to remove the mask layer used to block one or more portions of the substrate 102 during the first ion implantation. It is noted that, although not shown in FIGS. 2A and 2B, doping can also be performed in regions outside of the I/O well region 126, where the doping can be, but need not be, different from the doping performed in the I/O well region 126. In one or more implementations, the doping may utilize an in-situ conformal doping source (e.g., material is doped when grown) such as a doped oxide.

In one or more implementations, the substrate 102 receives a second mask layering such that the source/drain regions are exposed to a second ion implantation with a doping material different from that of the first ion implantation forming the first source region 104 and the drain region 106, for example.

The first gate structure 107 may be disposed on at least a portion of the I/O well region 126 and on at least a portion of the first source region 104. The first gate structure 107 may remain in place as the final gate structure of the split-gate semiconductor device 200, or the first gate structure 107 may be removed and replaced with alternative gate dielectric and/or gate electrode materials. Gate replacement processes, for example high-k metal gate (HKMG), are well-known in the semiconductor manufacturing field and are not further described herein.

In one or more implementations, a hardmask material is deposited and patterned using semiconductor fabrication techniques to form hardmask mandrels (not shown) on the top surface of the substrate 102. In one or more implementations, the patterning is performed using sidewall image transfer (SIT). The hardmask material can be, by way of example and not of limitation, oxide (e.g., silicon oxide) or nitride (e.g., silicon nitride).

In one or more implementations, etching is performed on the substrate 102 to remove one or more portions of the substrate 102 based on locations of the hardmask mandrels. In this regard, the substrate 102 is patterned by an etch operation to form one or more recessed regions in the substrate 102, after which the hardmask mandrels are removed.

In some aspects, the first isolation layer 112 is disposed into a recessed region formed in the substrate 102. For example, the first isolation layer 112 may be disposed adjacent to and in contact with at least the first source region 104 and the native section of the substrate 102. The first isolation layer 112 is thereafter recessed using an etch operation (e.g., wet etch or dry etch) to form a conformal surface with the first source region 104.

In one or more implementations, the first isolation layer 112 includes one or more layers of a high-k dielectric material and/or an oxide insulator material. For example, one or more layers of oxide material are deposited into the recessed region. The one or more layers of oxide material may be recessed as part of a STI process. The thickness of the recessed oxide material can be between 30 nm and 300 nm depending on implementation. The high-k dielectric material can include, but is not limited to, hafnium oxide, hafnium silicon oxide, lanthanum oxide, lanthanum aluminum oxide, yttrium oxide, lead zinc niobate, among other high-k dielectric materials identifiable by a person skilled in the art.

In one or more implementations, the oxide material can be deposited utilizing a molecular vapor deposition (MVD) process, although other suitable deposition processes may be utilized. The oxide material may be an oxide suitable for filling the trenches between formed (or patterned) semiconductor fin structures. The oxide material may have a low etch rate (such as a low hydrofluoric acid etch rate). Silicon dioxide (SiO₂) is generally used as the oxide material, although other suitable oxides can be used. The oxide material can be deposited utilizing a process such as a chemical vapor deposition (CVD), low pressure chemical vapor deposition (LPCVD), molecular layer deposition (MLD), among others.

The first gate structure 107 may be referred to as the “active” gate because during operation of a completed chip, the first gate structure 107 receives a signal that controls electrical conduction between the first source region 104 and the drain region 106. The current path between the first source region 104 and the drain region 106 includes the first source region 104, the core well region 210, referred to as the native section in this embodiment, the I/O well region 126 and the drain region 106. In contrast to the split-gate semiconductor device 100 of FIG. 1, the split-gate semiconductor device 200 includes laterally formed FET devices with smaller threshold voltages due to the smaller number of well implants in the substrate 102; thus reducing the junction capacitance to yield higher performing split-gate semiconductor devices.

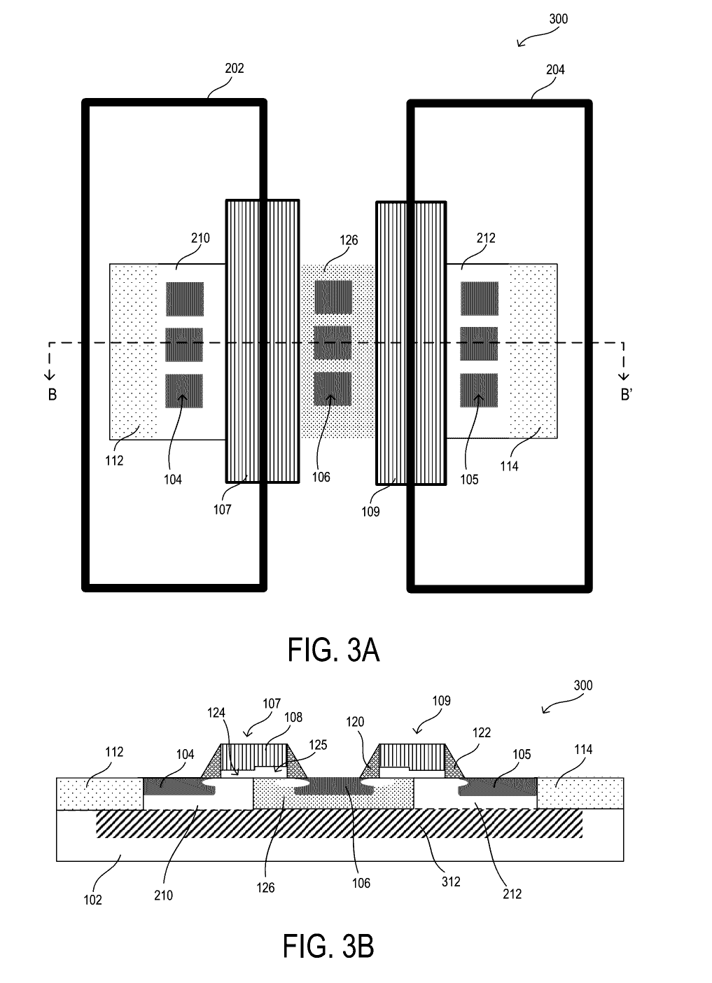

FIGS. 3A and 3B illustrate a planar view of a second split-gate semiconductor device with masked source regions and a cross-sectional view of the second split-gate semiconductor device along B-B′ according to one or more implementations. Not all of the depicted components may be required, however, and one or more implementations may include additional components not shown in the figure. Variations in the arrangement and type of the components may be made without departing from the scope of the claims as set forth herein. Additional components, different components, or fewer components may be provided.

Because the features described in FIGS. 2A and 2B are similar to the features of FIGS. 3A and 3B, only differences between the figures will be described in reference to FIGS. 3A and 3B. For purposes of simplification, the implementations described in FIGS. 3A and 3B will be discussed primarily in reference to the first gate structure 107, the first source region 104 and the drain region 106; however, the implementations may be similarly applied to the second gate structure 109 and the second source region 105.

In one or more implementations, the split-gate semiconductor device 300 includes a deep n-well (DNW) layer 312. In this regard, the threshold voltage for an n-type split-gate semiconductor device can be further reduced by a relatively larger current path present through the channel region due to the DNW layer 312. In some aspects, the DNW layer 312 is in contact with the substrate 102 such that the DNW layer 312 is disposed beneath the core well regions 210 and 212 (non-doped) including the I/O well region 126 (doped). In some implementations, the DNW layer 312 is formed within the substrate 102 as part of an ion implantation operation separate from the first ion implantation. For example, the DNW layer 312 may be implanted after the doping of the substrate 102 but prior to the first ion implantation.

By way of example, the split-gate semiconductor device 300 would have a smaller threshold voltage with the DNW layer 312 disposed on the substrate 102 compared to the split-gate semiconductor device 200. This is because the DNW layer 312 causes a larger current path to form through the channel region thereby allowing the threshold voltage to decrease. In contrast to the split-gate semiconductor device 100 of FIG. 1, the split-gate semiconductor device 300 includes laterally formed FET devices with smaller threshold voltages due to the smaller number of well implants in the substrate 102 including the presence of the DNW layer 312; thus reducing the junction capacitance to yield higher performing split-gate semiconductor devices.

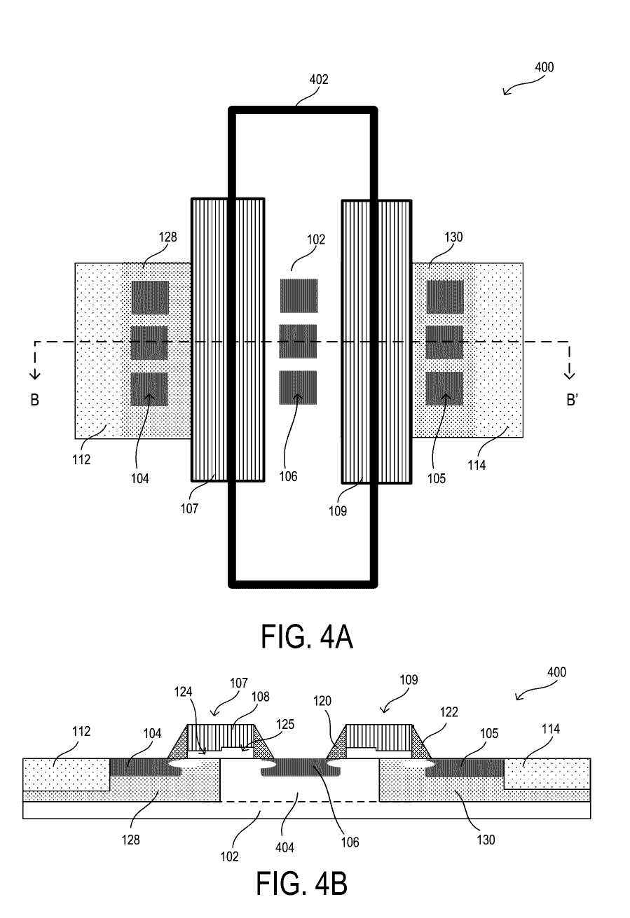

FIGS. 4A and 4B illustrate a planar view of a split-gate semiconductor device with a masked drain region and a cross-sectional view of the split-gate semiconductor device along B-B′ according to one or more implementations. Not all of the depicted components may be required, however, and one or more implementations may include additional components not shown in the figure. Variations in the arrangement and type of the components may be made without departing from the scope of the claims as set forth herein. Additional components, different components, or fewer components may be provided.

Because the features described in FIGS. 2A and 2B are similar to the features of FIGS. 4A and 4B, only differences between the figures will be described in reference to FIGS. 4A and 4B. For purposes of simplification, the implementations described in FIGS. 4A and 4B will be discussed primarily in reference to the first gate structure 107, the first source region 104 and the drain region 106; however, the implementations may be similarly applied to the second gate structure 109 and the second source region 105.

In order to lower the threshold voltage of the laterally formed split-gate semiconductor devices, the split-gate semiconductor device 400 includes a section of the substrate 102 designated as an I/O well region blocked from a first ion implantation. In this embodiment, the I/O well region 126 (FIG. 1) is defined as a native layer (or section) of the substrate 102 in contact with the drain region 106 and the second gate oxide 125, referred to as an I/O well region 404. The I/O well region 404 does not include any well doping in order to increase current flow through the channel region thereby lowering the threshold voltage characteristics. In this respect, the threshold voltage is determined by the thin gate oxide (e.g., the first gate oxide 124).

During the first ion implantation, such as a well implantation to implant a p-type material into the substrate 102, the I/O well region 404 is blocked from receiving the p-type well implants while one or more regions designated as core well regions (e.g., the core well regions 128 and 130) are not blocked thereby exposed to the first ion implantation. In this respect, the threshold voltage for the split-gate semiconductor device 200 becomes a function of the core well implants (e.g., the core well regions 128 and 130) and pocket implants (e.g., the first source region 104, the drain region 106). In contrast, the threshold voltage for the split-gate semiconductor device 100 would be higher since the threshold voltage for such device is a function of the core well implants and the 10 well implant as well as the source/drain pocket implants. As shown in FIG. 4A, a mask layer 402 is provided on a region of the substrate 102 in order to protect the I/O well region 404 from receiving the well implant dopants through the first ion implantation.

In one or more implementations, the substrate receives a first mask layering over one or more regions of the substrate designated as the I/O well region 404 such that the remainder of the substrate is then exposed to the first ion implantation to form the core well regions 128 and 130. In turn, the substrate 102 receives a second mask layering such that the source/drain regions are exposed to a second ion implantation with a doping material different from that of the first ion implantation forming the first source region 104 and the drain region 106, for example.

The current path between the first source region 104 and the drain region 106 includes the first source region 104, the core well region 128, the I/O well region 404, referred to as the native section in this embodiment, and the drain region 106. In contrast to the split-gate semiconductor device 100 of FIG, 1, the split-gate semiconductor device 200 includes laterally formed FET devices with smaller threshold voltages due to the smaller number of well implants in the substrate 102; thus reducing the junction capacitance to yield higher performing split-gate semiconductor devices.

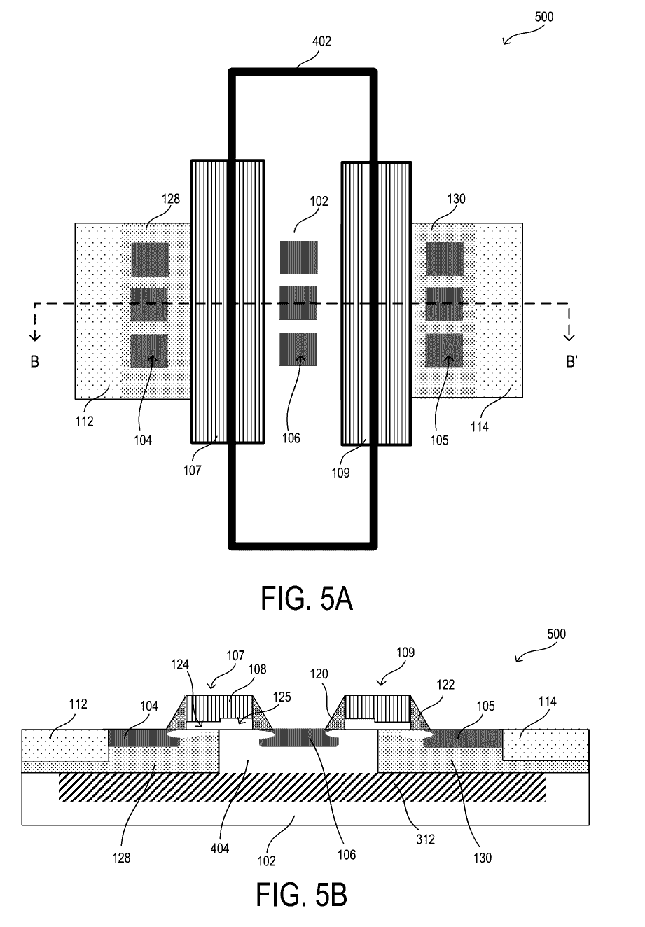

FIGS. 5A and 5B illustrate a planar view of a second split-gate semiconductor device with a masked drain region and a cross-sectional view of the second split-gate semiconductor device along B-B′ according to one or more implementations. Not all of the depicted components may be required, however, and one or more implementations may include additional components not shown in the figure. Variations in the arrangement and type of the components may be made without departing from the scope of the claims as set forth herein. Additional components, different components, or fewer components may be provided.

Because the features described in FIGS. 4A and 4B are similar to the features of FIGS. 5A and 5B, only differences between the figures will be described in reference to FIGS. 5A and 5B. For purposes of simplification, the implementations described in FIGS. 5A and 5B will be discussed primarily in reference to the first gate structure 107, the first source region 104 and the drain region 106; however, the implementations may be similarly applied to the second gate structure 109 and the second source region 105.

In one or more implementations, the split-gate semiconductor device 500 includes a deep n-well (DNW) layer 312. In this regard, the threshold voltage for an n-type split-gate semiconductor device can be further reduced by a relatively larger current path present through the channel region due to the DNW layer 312. In some aspects, the DNW layer 312 is in contact with the substrate 102 such that the DNW layer 312 is disposed beneath the core well regions 128 and 130 (doped) including the I/O well region 404 (non-doped). In some implementations, the DNW layer 312 is formed within the substrate 102 as part of an ion implantation operation separate from the first ion implantation. For example, the DNW layer 312 may be implanted after the doping of the substrate 102 but prior to the first ion implantation.

By way of example, the split-gate semiconductor device 500 would have a smaller threshold voltage with the DNW layer 312 disposed on the substrate 102 compared to the split-gate semiconductor device 400. This is because the DNW layer 312 causes a larger current path to form through the channel region thereby allowing the threshold voltage to decrease. In contrast to the split-gate semiconductor device 100 of FIG. 1, the split-gate semiconductor device 500 includes laterally formed FET devices with smaller threshold voltages due to the smaller number of well implants in the substrate 102 including the presence of the DNW layer 312; thus reducing the junction capacitance to yield higher performing split-gate semiconductor devices.

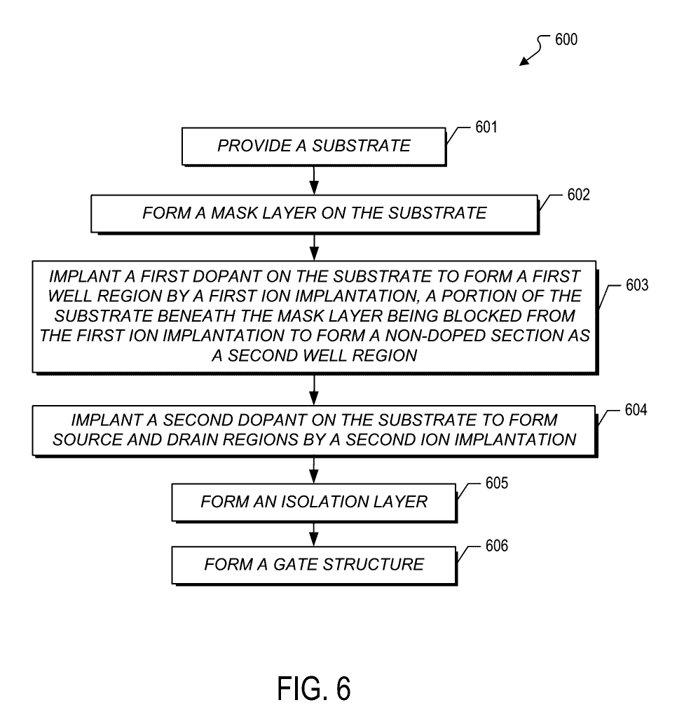

FIG. 6 illustrates a sequential fabrication process for forming a split-gate semiconductor device according to one or more implementations. Further for explanatory purposes, the blocks of the sequential fabrication process 600 are described herein as occurring in serial, or linearly. However, multiple blocks of the sequential fabrication process 600 may occur in parallel. In addition, the blocks of the sequential fabrication process 600 need not be performed in the order shown and/or one or more of the blocks of the sequential fabrication process 600 need not be performed.

In this embodiment, the sequential fabrication process 600 relates to fabricating a semiconductor device including a split-gate semiconductor device with native well regions. The sequential fabrication process 600 includes providing a substrate (601). The sequential fabrication process 600 includes forming a mask layer on at least a first portion of the substrate (602).

The sequential fabrication process 600 includes implanting a first dopant on the substrate to form a first well region in the substrate by a first ion implantation (603). In one or more implementations, the at least a portion of the substrate beneath the mask layer is blocked from the first ion implantation to form a native (or non-doped) section, referred to as a second well region.

The sequential fabrication process 600 includes implanting a second dopant on the substrate to form source and drain regions in the substrate by a second ion implantation (604). In this embodiment, the second dopant (e.g., p-type material) is different from the first dopant n-type material). Alternatively, the second dopant may be n-type material and the first dopant may be p-type material depending on implementation.

The sequential fabrication process 600 includes patterning the substrate to form one or more isolation layers adjacent to and in contact with at least the source regions and well regions (605). In some aspects, the isolation layers are in contact with source regions and doped core well regions (the I/O well region being the native section). In other aspects, the isolation layers are in contact with the source regions and non-doped (or native) core well regions (the I/O well region being the doped section). The sequential fabrication process 600 also includes forming a gate structure on at least a portion of the core well region and on at least a portion of the I/O well region (607).

The sequential fabrication process 600 may include forming a third well region as part of a second native section of the substrate blocked from the first ion implantation. The second native section may have a same doping concentration as that of the native section, in which the first well region is located being between the second well region and the third well region. The sequential fabrication process 600 may include forming a second gate structure on at least a portion of the first well region and at least a portion of the third well region.

The sequential fabrication process 600 may include removing the mask layer by an etch operation before the gate structure is formed. The sequential fabrication process 600 may include forming a deep n-well layer in the substrate by a second first ion implantation, in which the deep n-well layer is located beneath the first well region and the second well region.

As described herein, the subject disclosure relates to a split-gate semiconductor device which can support both low operating voltages (e.g., core) and high operating voltages (e.g., I/O) with the flexibility of reducing the threshold voltage by blocking well implants for certain well regions of the device. In one or more implementations, the core well is blocked when the I/O well receives well implants from a first ion implantation. In other implementations, the I/O well is blocked when the core well receives well implants from a second first ion implantation. In this regard, the number of well implants containing well dopants will be smaller compared to conventional devices containing well implants in all designated well regions. As a result, the sum of pocket implants and well implants will be smaller thereby forming a smaller threshold voltage for such FET device. In addition, the resistance across the source and drain of the device will be smaller due to the lesser number of regions between the source and drain containing well implants. At a junction between a well region with well implants and an adjacent well region blocked from well implants, the junction capacitance will be smaller compared to conventional devices having adjacent well regions implanted with dopants. Another advantage of the aforementioned FET devices is that no additional fabrication process operations are needed to construct the transistor structures in accordance with one or more implementations of the subject technology.

A semiconductor device includes a substrate having a doped section and a native section. The doped section is implanted with a first dopant by a first ion implantation forming a first well region. The native section is blocked from the first ion implantation forming a second well region. The substrate has a first terminal region and a second terminal region implanted with a second dopant by a second ion implantation. The first terminal region is disposed within the doped section and the second terminal region is disposed within the native section. The semiconductor device also includes a gate structure disposed on at least a portion of the first well region and on at least a portion of the second well region. The gate structure has a gate dielectric layer having a first region with a thickness different from that of a second region of the gate dielectric layer. The first region of the gate dielectric layer is located on the first well region and the second region of the gate dielectric layer is located on the second well region.

A semiconductor device includes a substrate having a doped section and a native section. The doped section is implanted with a first dopant by a first ion implantation forming a first well region. The native section is blocked from the first ion implantation forming a second well region. The substrate has a first terminal region and a second terminal region implanted with a second dopant by a second ion implantation. The first terminal region is disposed within the doped section and the second terminal region is disposed within the native section. The semiconductor device includes a first well region disposed in the doped section. The first well region is implanted with a first dopant by a first ion implantation. The semiconductor device includes a second well region disposed in the native section. The second well region is blocked from the first ion implantation forming part of the native section. The semiconductor device includes a first terminal region and a second terminal region implanted with a second dopant by a second ion implantation. The first terminal region is disposed in the first well region and the second terminal region is disposed in the second well region. The semiconductor device includes a gate dielectric layer having a first region with a first thickness and a second region with a second thickness. The second thickness may be greater than the first thickness. The first region of the gate dielectric layer is located on the first well region and the second region of the gate dielectric layer is located on the second well region. The semiconductor device also includes a gate electrode disposed on the gate dielectric layer forming a gate structure on the substrate.

A method of fabricating a semiconductor device includes providing a substrate and forming a mask layer on one or more portions of the substrate. The method includes implanting a first dopant on the substrate by a first ion implantation to form a doped section of the substrate. The one or more portions of the substrate beneath the mask layer may be blocked from the first ion implantation to form a native section of the substrate. The native section has a doping concentration same as that of the substrate. The doped section has a doping concentration greater than that of the substrate. The doped section has a first well region and the native section has a second well region. The method includes implanting a second dopant on the first well region and the second well region by a second ion implantation to respectively form a first terminal region and a second terminal region. The method also includes forming a gate structure on at least a portion of the first well region and on at least a portion of the second well region. The gate structure comprises a gate dielectric region having a first region with a first thickness and a second region with a second thickness, where the first thickness is different from the second thickness. The first region may be abutting the second region.

As used herein, the terms “chip,” “die,” “integrated circuit,” “semiconductor device,” are applicable to the subject technology as these terms can be used interchangeably in the field of electronics. With respect to a chip, power, ground, and various signals may be coupled between them and other circuit elements via physical, electrically conductive connections. Such a point of connection may be referred to as an input, output, input/output (I/O), terminal, line, pin, pad, port, interface, or similar variants and combinations. Although connections between and amongst chips can be made by way of electrical conductors, chips and other circuit elements may alternatively be coupled by way of, but not limited to, optical, mechanical, magnetic, electrostatic, and electromagnetic interfaces.

In the semiconductor industry environment of foundries and fabless companies, it is the foundries that develop, specify and provide the physical structures that designers use to implement their designs. Foundries provide manufacturing services to many fabless semiconductor companies, but to operate profitably, they must optimize their manufacturing processes to achieve high yields. Such optimizations typically require that limitations be placed on the variety of structures that can be produced by a particular manufacturing process. Foundries typically provide a limited set of transistor structures that are intended to cover a broad range of circuit applications.

One or more implementations are performed by one or more integrated circuits, such as application specific integrated circuits (ASICs) or field programmable gate arrays (FPGAs). In one or more implementations, such integrated circuits execute instructions that are stored on the circuit itself. The term “integrated circuit” or “semiconductor device” may include, but is not limited to, a design tool output file as binary code encompassing the overall physical design of the integrated circuit or semiconductor device, a data file encoded with code representing the overall physical design of the integrated circuit or semiconductor device, a packaged integrated circuit or semiconductor device, or an unpackaged die. The data file can include elements of the integrated circuit or semiconductor device, interconnections of those elements, and timing characteristics of those elements (including parasitics of the elements).

The various illustrative blocks, elements, components, and methods described herein may be implemented as electronic hardware. Various illustrative blocks, elements, components, and methods have been described above generally in terms of their functionality. Whether such functionality is implemented as hardware depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

Terms such as “top,” “bottom,” “above,” “below,” “beneath,” “side,” “horizontal,” “vertical,” and the like refer to an arbitrary frame of reference, rather than to the ordinary gravitational frame of reference. Thus, such a term may extend upwardly, downwardly, diagonally, or horizontally in a gravitational frame of reference.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. Such disclosure may provide one or more examples. A phrase such as an aspect may refer to one or more aspects and vice versa, and this applies similarly to other phrases.

Any implementation described herein as an “example” is not necessarily to be construed as preferred or advantageous over other implementations. Furthermore, to the extent that the term “include,” “have,” or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112, sixth paragraph, unless the element is expressly recited using the phrase “means for” or, in the case of a method claim, the element is recited using the phrase “step for.”

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more.” Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

1. A semiconductor device, comprising:
a substrate having a doped section and a native section, the doped section implanted with a first dopant by a first ion implantation forming a first well region, the native section blocked from the first ion implantation forming a second well region, the substrate having a first terminal region and a second terminal region implanted with a second dopant by a second ion implantation, the first terminal region disposed within the doped section, the second terminal region disposed within the native section; and
a gate structure disposed on at least a portion of the first well region and on at least a portion of the second well region, the gate structure having a gate dielectric layer, the gate dielectric layer having a first region with a thickness different from that of a second region of the gate dielectric layer, the first region of the gate dielectric layer located on the first well region and the second region of the gate dielectric layer located on the second well region.

2. The semiconductor device of claim 1, further comprising a deep n-well layer disposed within the substrate by a the second first ion implantation, the deep n-well layer located beneath the first well region and the second well region.

3. The semiconductor device of claim 1, wherein the native section has a first doping concentration smaller than a second doping concentration of the doped section.

4. The semiconductor device of claim 1, further comprising:
a second native section of the substrate, the second native section blocked from the first ion implantation forming a third well region, the second native section having a same doping concentration as that of the native section, the first well region being between the second well region and the third well region; and
a second gate structure disposed on at least a portion of the first well region and at least a portion of the third well region.

5. The semiconductor device of claim 1, wherein the first terminal region is a drain terminal and the second terminal region is a source terminal.

6. The semiconductor device of claim 5, wherein the first well region is associated with a first operating voltage and the second well region is associated with a second operating voltage, and wherein the first operating voltage is greater than the second operating voltage.

7. The semiconductor device of claim 6, wherein the first region has a first thickness greater than a second thickness of the second region.

8. The semiconductor device of claim 7, wherein the first dopant is p-type semiconductor material and the second dopant is n-type semiconductor material, and wherein the gate structure includes one or more layers of n-type semiconductor material.

9. The semiconductor device of claim 7, wherein the first dopant is n-type semiconductor material and the second dopant is p-type semiconductor material, and wherein the gate structure includes one or more layers of p-type semiconductor material.

10. The semiconductor device of claim 7, wherein the first well region includes n-type semiconductor material, and wherein the second well region includes a same semiconductor material as the substrate.

11. The semiconductor device of claim 7, wherein the first well region includes p-type semiconductor material, and wherein the second well region includes a same semiconductor material as the substrate.

12. The semiconductor device of claim 1, wherein the first terminal region is a source terminal and the second terminal region is a drain terminal.

13-20. (canceled)

21. A semiconductor device, comprising:
a substrate having a doped section and a native section, the doped section implanted with a first dopant by a first ion implantation, the native section excluding the first dopant;
a first well region disposed in the doped section, the first well region implanted with the first dopant;
a second well region disposed in the native section, the second well region blocked from the first ion implantation forming part of the native section;
a first terminal region and a second terminal region implanted with a second dopant by a second ion implantation, the first terminal region disposed in the first well region, the second terminal region disposed in the second well region; and
a gate structure disposed on at least a portion of the first well region and on at least a portion of the second well region, the gate structure having a gate dielectric layer, the gate dielectric layer having a first region with a thickness different from that of a second region of the gate dielectric layer, the first region of the gate dielectric layer located on the first well region and the second region of the gate dielectric layer located on the second well region.

22. The semiconductor device of claim 21, further comprising a deep n-well layer disposed within the substrate by ion implantation, the deep n-well layer located beneath the first well region and the second well region.

23. The semiconductor device of claim 21, wherein the native section has a first doping concentration smaller than a second doping concentration of the doped section.

24. The semiconductor device of claim 21, further comprising:
a second native section of the substrate, the second native section blocked from the first ion implantation forming a third well region, the second native section having a same doping concentration as that of the native section, the first well region being between the second well region and the third well region; and
a second gate structure disposed on at least a portion of the first well region and at least a portion of the third well region.

25. The semiconductor device of claim 21, wherein:
the first terminal region is a drain terminal and the second terminal region is a source terminal,
the first well region is associated with a first operating voltage and the second well region is associated with a second operating voltage, and wherein the first operating voltage is greater than the second operating voltage, and
the first region has a first thickness greater than a second thickness of the second region,

26. The semiconductor device of claim 21, wherein:
the first dopant is p-type semiconductor material and the second dopant is n-type semiconductor material,
the gate structure includes one or more layers of n-type semiconductor material, and
the second well region includes a same semiconductor material as the substrate.

27. The semiconductor device of claim 21, wherein:
the first dopant is n-type semiconductor material and the second dopant is p-type semiconductor material,
the gate structure includes one or more layers of p-type semiconductor material, and
the second well region includes a same semiconductor material as the substrate.

28. A semiconductor device, comprising:
a substrate having a doped section and a native section, the doped section implanted with a first dopant by a first ion implantation;
a first well region disposed in the doped section;
a second well region disposed in the native section, the second well region blocked from the first ion implantation forming part of the native section;
a first terminal region and a second terminal region implanted with a second dopant by a second ion implantation, the first terminal region disposed in the first well region, the second terminal region disposed in the second well region;
a gate dielectric layer having a first region with a first thickness and a second region with a second thickness, the first thickness being different from the second thickness, the first region of the gate dielectric layer located on the first well region, the second region of the gate dielectric layer located on the second well region; and
a gate electrode disposed on the gate dielectric layer forming a gate structure on the substrate.
